(19) United States
(12) Patent Application Publication
(10) Pub. No.: US 2019/0306989 A1
(43) Pub. Date: Oct. 3, 2019

(54) REAL-TIME DETECTION AND CORRECTION OF PRINTED CIRCUITRY

(71) Applicant: Konica Minolta Laboratory U.S.A., Inc., San Mateo, CA (US)

(72) Inventors: John Randall Christ, Santa Clara, CA (US); Jun Amano, Hillsborough, CA (US); Leiming Wang, Foster City, CA (US)

(73) Assignee: Konica Minolta Laboratory U.S.A., Inc., San Mateo, CA (US)

(21) Appl. No.: 15/942,047

(22) Filed: Mar. 30, 2018

(51) Int. Cl. H05K 3/22; B41M 3/00; H05K 3/12; G01R 31/28

(52) U.S. Cl. CPC H05K 3/225; B41M 3/006; H05K 3/12; H05K 2203/0126; H05K 2203/163; H05K 2203/1105; H05K 2203/0121; G01R 31/2812

(57) ABSTRACT

A method is provided for detecting faults in a conductive circuitry. The method includes: printing the conductive circuitry on top of a substrate using a printing head; heating the conductive circuitry with a heat source; scanning the heated conductive circuitry with a non-contact thermal detector; detecting, with the non-contact thermal detector and concurrently with the printing of the conductive circuitry, the faults where the printing head failed to print; and reprinting the faults with the printing head.

### BACKGROUND

Printing conductive patterns (e.g., conductive wires) on substrates (e.g., a circuit board) may leave faulty disconnections or poor connections (i.e., faults) that compromise functionality and lifetime of the conductive patterns. To repair the faults, the substrates may be reloaded into a printing machine and the printing may be re-done or the faults manually rewritten with a conductive pen. However, these methods are not only time consuming but also unreliable and expensive.

### SUMMARY

In general, in one aspect, the invention relates to a method for detecting faults in a conductive circuitry. The method comprises: printing the conductive circuitry on top of a substrate using a printing head; heating the conductive circuitry with a heat source; scanning the heated conductive circuitry with a non-contact thermal detector; detecting, with the non-contact thermal detector and concurrently with the printing of the conductive circuitry, the faults where the printing head failed to print; and reprinting the faults with the printing head.

In general, in one aspect, the invention relates to a non-transitory computer readable medium (CRM) storing instructions that causes a print server to perform an operation for detecting faults in a conductive circuitry embodied therein. The operation comprises: printing the conductive circuitry on top of a substrate using a printing head; heating the conductive circuitry with a heat source; scanning the heated conductive circuitry with a non-contact thermal detector; detecting, with the non-contact thermal detector and concurrently with the printing of the conductive circuitry, the faults where the printing head failed to print; and reprinting the faults with the printing head.

In general, in one aspect, the invention relates to a system for detecting faults in a conductive circuitry. The system comprises: a memory; and a computer processor connected to the memory. The computer processor causes a print unit coupled to the system to: print the conductive circuitry on top of a substrate using a printing head; heat the conductive circuitry with a heat source; scan the heated conductive circuitry with a non-contact thermal detector; detect, with the non-contact thermal detector and concurrently with the print of the conductive circuitry, the faults where the printing head failed to print; and reprint the faults with the printing head.

Other aspects of the invention will be apparent from the following description and the appended claims.

### BRIEF DESCRIPTION OF DRAWINGS

FIG. 1 shows a system in accordance with one or more embodiments of the invention.

FIG. 2 shows a flowchart in accordance with one or more embodiments of the invention.

FIGS. 3A-3B show implementation examples in accordance with one or more embodiments of the invention.

FIGS. 4A-4B show implementation examples in accordance with one or more embodiments of the invention.

FIGS. 5A-5B show implementation examples in accordance with one or more embodiments of the invention.

FIGS. 6A-6B show implementation examples in accordance with one or more embodiments of the invention.

FIG. 7 shows a computing system in accordance with one or more embodiments of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In general, embodiments of the invention provide a method, a non-transitory computer readable medium (CRM), and a system for detecting and correcting faulty-printed conductive circuits (i.e., conductive pattern) on a substrate (e.g., a circuit board) concurrently with a process of printing the conductive circuit on the substrate. When a printing system prints a conductive pattern (e.g., conductive lines that may connect circuit elements of a circuit board) with a printing head on a substrate, any type of errors in the printing process (e.g., low level of conductive ink, incorrect pressure in a supply tank to the printing head, an error in the printing head, contamination on the substrate, or cracks in the substrate) may occur. These errors may leave areas of poor connections (i.e., faults) on the substrate that were not part of the originally-designed conductive pattern.

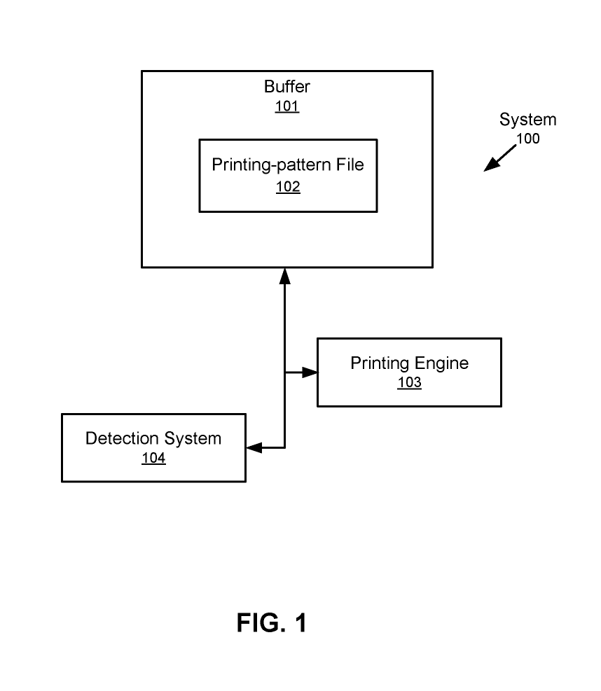

FIG. 1 shows a system (100) in accordance with one or more embodiments of the invention. As seen in FIG. 1, the system (100) has multiple components, including, for example, a buffer (101), a printing engine (103), and a detection system (104). Each of these components (101, 103, 104) may be located on the same computing device (e.g., personal computer (PC), laptop, tablet PC, smart phone, multifunction printer, kiosk, server, etc.) or on different computing devices connected by a network of any size having wired and/or wireless segments.

In one or more embodiments of the invention, the buffer (101) may be implemented in hardware (i.e., circuitry), software, or any combination thereof. The buffer (101) is configured to store a printing-pattern file (102) of the conductive pattern. In one or more embodiments, the printing-pattern file (102) may include a design of the conductive pattern and print instructions. The printing-pattern file (102) may be an image and/or a graphic (e.g., a stereolithography (STL) format, a virtual reality model language (VRML) format file, an additive manufacturing file (AMF) format, etc.). The printing-pattern file (102) may be obtained (e.g., downloaded, created locally, etc.) from any source.

In one or more embodiments of the invention, the printing engine (103) may be implemented in hardware (i.e., circuitry), software, or any combination thereof. The printing engine (103) may be coupled to a printing head that prints the conductive pattern based on the printing-pattern file (102) on a substrate. In one or more embodiments, the detection system (104) may be implemented in hardware (i.e., circuitry), software, or any combination thereof. The detection system (104) detects the faults in the conductive pattern. Upon receiving information about the faults (e.g., the locations of the faults) from the detection system (104), the printing engine (103) reprints the faults.

In one or more embodiments of the invention, the detection system (104) may include a heating unit that heats the conductive pattern to radiate a thermal signal profile (e.g., infrared (IR) waves). The detection system (104) may also include a non-contact thermal detector (e.g., an IR camera) that can scan the conductive pattern in a non-contact mode (i.e., no physical contact between the thermal detector and the conductive pattern) in concurrent (i.e., simultaneously) with the printing of the conductive pattern. This captures the thermal signal profile of the conductive pattern. In the thermal signal profile of the conductive pattern the faults do not radiate or have a weaker radiation in comparison with correctly-printed areas of the conductive pattern because the faults have no conductive material or have less conductive material than the correctly-printed areas. Thus, the faults may be detected and located on the substrate.

In one or more embodiments of the invention, the non-contact thermal detector may be a thermal sensor array (i.e., an array of thermal sensors or thermal sensor pixels that are arranged side-by-side). The thermal sensor array may be any one of a thermal IR, line-scanner, fiber optic thermometer, etc.

In one or more embodiments of the invention, after locating a fault, the printing head may move to the location of the fault and reprint the conductive pattern in that location. The printing head may pause the printing of the circuit pattern immediately after a fault is located and moves to the location of the fault to reprint the conductive pattern in that location. Alternatively, the printing head may complete printing a part or the whole conductive pattern and then move back to the location of the fault to reprint in that location.

In one or more embodiments of the invention, artificial intelligence (AI) or machine learning techniques may be used to improve the detection of the faults. For this purpose, common failure patterns (e.g., failure patterns for a specific printer type, a specific printing material formulation, etc.) may be collected and analyzed to prepare a common failure pattern database. For example, by using a specific type of substrate, printer, or printing materials at a specific ambient temperature or in a specific altitude, the faults may be more likely to happen toward specific locations of the substrate. The AI and machine learning techniques may modify printing techniques based on the information stored in the common failure pattern database that includes results of the analysis of the common failure patterns in these conditions to better eliminate the faults.

In one or more embodiments of the invention, detection and reprinting of the faults concurrently with the printing prevents printing-rework post-processes that may be expensive, time consuming, and unreliable. In addition, bonding wires to a reworked conductive pattern may be challenging. Moreover, because printing materials may vary from batch to batch, repairing the faults manually or in a printing-rework post-process may create non-uniform conductive patterns.

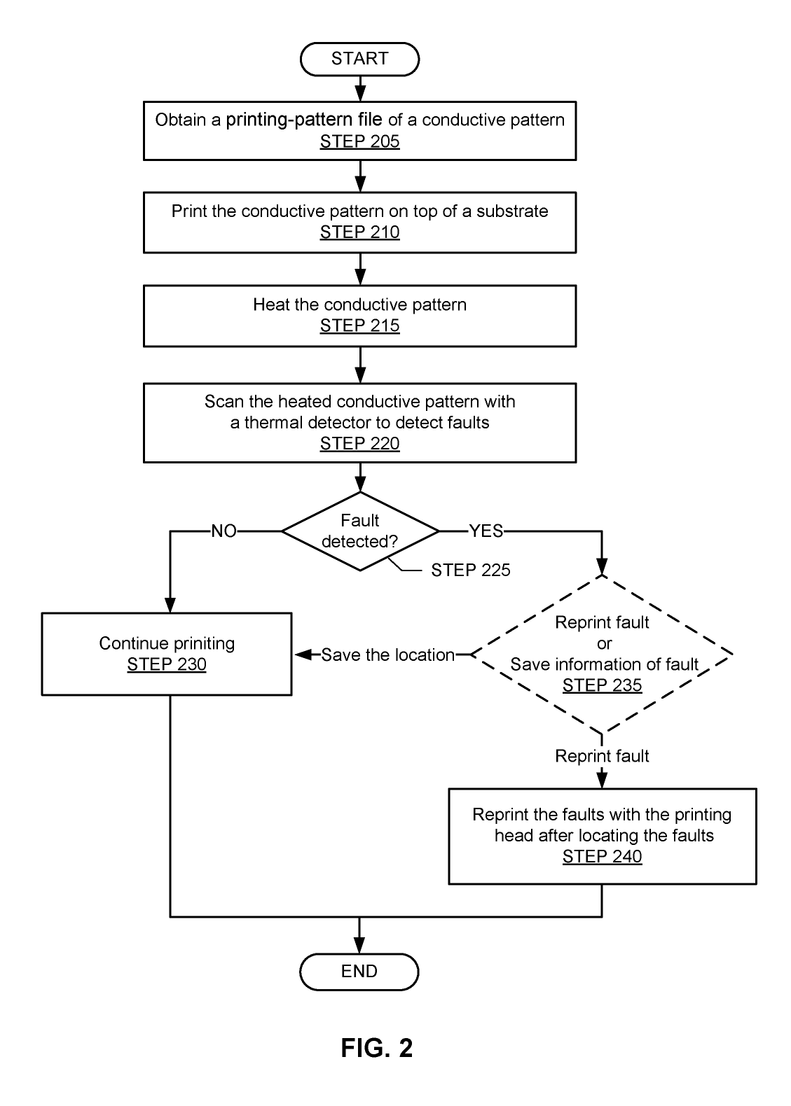

The processes described above in reference to FIG. 1 are exemplified in more detail below with reference to FIGS. 2, 3A-3B, 4A-4B, 5A-5B, and 6A-6B.

Although the system (100) is shown as having three components (101, 103, 104), in other embodiments of the invention, the system (100) may have more or fewer components. Further, the functionality of each component described above may be split across components. Further still, each component (101, 103, 104) may be utilized multiple times to carry out an iterative operation.

FIG. 2 shows a flowchart in accordance with one or more embodiments of the invention. The flowchart depicts a method for simultaneously correcting the faults during printing a conductive pattern (i.e., real-time fault correction). One or more of the steps in FIG. 2 may be performed by the components of the system (100), discussed above in reference to FIG. 1. Specifically, one or more steps in FIG. 2 may be performed by the printing engine (103) and the detection system (104) as discussed above in reference to FIG. 1. In one or more embodiments, one or more of the steps shown in FIG. 2 may be omitted, repeated, and/or performed in a different order than the order shown in FIG. 2. Accordingly, the scope of the invention should not be considered limited to the specific arrangement of steps shown in FIG. 2.

Referring to FIG. 2, as discussed above in reference to FIG. 1, initially, a printing-pattern file of a conductive pattern is obtained (STEP 205). For example, the system (100) may obtain the printing-pattern file (102) and store it in the buffer (101). In one or more embodiments, the printing-pattern file may include a schematic of the conductive pattern, printing instructions or any other parameters that are needed for printing the conductive pattern. The printing-pattern file may include lines, gaps, or any other design elements that may be used to lay out a conductive pattern.

In STEP 210, as discussed above in reference to FIG. 1, a printing head prints a conductive pattern on top of a substrate. In one or more embodiments, to print the conductive pattern, the printing head may deposit a material (i.e., printing material) on the substrate. The printing head may move on top of the substrate. Alternatively, the substrate may move with respect to the printing head to print the printing material. The substrate may be made from an insulator or an IR-transparent material.

In one or more embodiments of the invention, the printing materials may have both highly electrical and thermal conductive characteristics, such as silver nanoparticles, copper nanoparticles, indium tin oxide (ITO) particles, graphene flakes, etc.

In one or more embodiments of the invention, the substrate materials may have both highly electrical and thermal insulating characteristics, such as glass, a polymer (e.g., polyethylene terephthalate (PET), polyethylene naphthalate (PEN), etc.), and polychlorinated biphenyl (PCB). The substrate materials may be either optically transparent or opaque for visible wavelength (400 nm-750 nm). For the case of a non-contact thermal detector being underneath the substrate, the substrate materials may be transparent in a range of IR wavelength (e.g., an IR range between 1-14 μm).

In one or more embodiments of the invention, the printing head deposits the printing materials in a pattern of lines. In one or more embodiments, the pattern of lines in the conductive pattern may have a width as thin as a few microns or as wide as a few millimeters.

In STEP 215, as discussed above in reference to FIG. 1, a heating unit (i.e., thermal source) heats the conductive pattern. In one or more embodiments, the heating unit may radiate heat directly to the conductive pattern. Alternatively, the thermal source may induce heat in the conductive pattern by indirect methods such as microwave or radio frequency (RF) radiation on the conductive pattern. In one or more embodiments, other suitable heating methods such as inductive heating (i.e., using an electrical current coupled to the conductive pattern to induce an eddy current in the conductive pattern) may also be used.

In STEP 220, as discussed above in reference to FIG. 1, a non-contact thermal detector scans the heated conductive pattern simultaneously with the printing of the conductive pattern to capture a thermal signal profile of the conductive pattern. In the thermal signal profile of the conductive pattern the faults will be detected and located on the substrate because the faults do not radiate or have a weaker radiation in comparison with correctly-printed areas of the conductive pattern.

In one or more embodiments of the invention, the non-contact thermal detector may have a resolution of a few microns.

In STEP 225, as discussed above in reference to FIG. 1, a determination is made as to whether a fault is detected.

In STEP 230, as discussed above in reference to FIG. 1, if a fault is not detected, the printing head continues to print the conductive pattern.

In STEP 240, as discussed above in reference to FIG. 1, if a fault is detected, the printing head moves to the area or location of the fault and reprints the fault (i.e., reprints the conductive pattern in the area or location of the detected fault).

In one or more embodiments, as discussed above in reference to FIG. 1, determination STEP 235 may be added to determine whether to reprint the fault or save the information of the fault (e.g., location, size, etc.) for reprinting the fault at a later time. If a determination is made in STEP 235 to reprint the fault, the process proceeds to STEP 240 to reprint the fault. If a determination is made in STEP 235 to save the information of the fault for reprinting the fault at a later time, the process moves to STEP 230 to continue the printing of the conductive pattern.

In one or more embodiment of the invention, the printing head may pause the printing of the conductive pattern immediately after locating the fault and move to the location of the fault to reprint the conductive pattern in that location. Alternatively, the printing head may complete printing a part or the whole conductive pattern and then move back to the location of the fault to reprint the conductive pattern in that location.

In one or more embodiments of the invention, STEPS 205-240 of FIG. 2 discussed above may be executed by a printer. Additionally, STEPS 215-240 may be repeated until each fault on the substrate has been detected and reprinted (i.e., fixed).

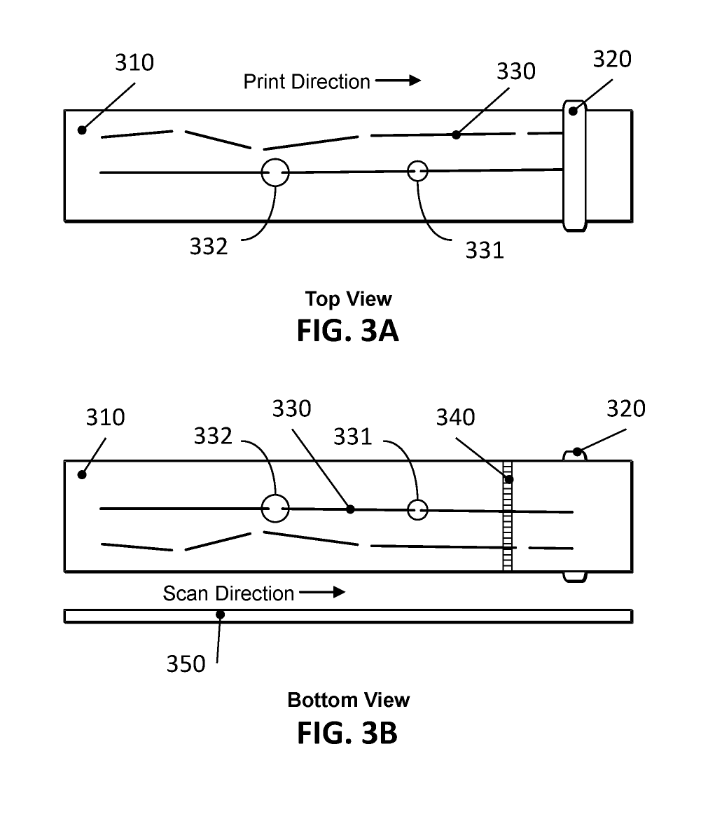

FIGS. 3A-3B, 4A-4B, 5A-5B, and 6A-6B show implementation examples in accordance with one or more embodiments of the invention. The exemplified method for real-time fault correction described above in reference to FIGS. 1 and 2 are applied in the implementation examples shown in FIGS. 3A-3B, 4A-4B, 5A-5B, and 6A-6B.

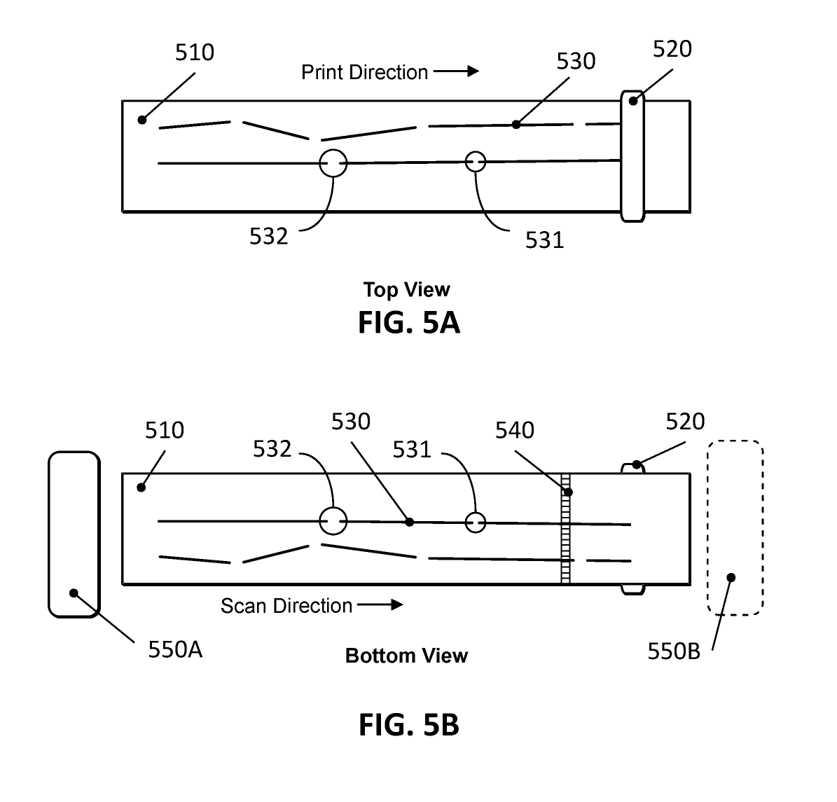

FIGS. 3A-3B and 5A-5B show printing setups to print conductive patterns on substrates. Each of the printing setups shown in FIGS. 3A-3B and 5A-5B include a substrate (310, 510), a printing head (320, 520) disposed on the substrate (310, 510), a non-contact thermal detector (340, 540) disposed under the substrate, and a heating unit (350, 550). The printing head (320, 520) prints the conductive pattern (330, 530) in a print direction across the substrate (310, 510). While printing, the printing head (320, 520) may leave (i.e., cause) some faults (331, 531) in the conductive pattern (330, 530).

In one or more embodiments of the invention, to increase a temperature of the conductive pattern (330, 530) with respect to a temperature of the substrate (310, 510), the heating unit (350, 550) heats the conductive pattern (330, 530).

In one or more embodiments of the invention, the non-contact thermal detector (340, 540) scans a thermal signal profile of the conductive pattern (330, 530) and detects the faults (331, 531) based on a heat profile of the conductive pattern (330. 530).

In one or more embodiment of the invention, the non-contact thermal detector (340, 540) may be disposed in such a way that moves and scans across the print direction (i.e., a length-wise direction across a length of the substrate (310, 510)) while being synchronized with movements of the printing head (320, 520). For example, the printing head (320, 520) and the non-contact thermal detector (340, 540) may be disposed on a lever (e.g., a rigid holder that holds the printing head (320, 520) and the non-contact thermal detector (340, 540)) in such a way that a distance between the printing head (320, 520) and the non-contact thermal detector (340, 540) along the print direction is constant as the printing head is printing.

In one or more embodiments of the invention, the conductive pattern (330, 530) may include multiple intentional gaps (332, 532) between conductive lines (i.e., gaps that appear in the printing-pattern file) in the conductive pattern (330, 530). To prevent mistakenly capturing the intentional gaps (332, 532) as faults (331, 531), the non-contact thermal detector (340, 540) may stop scanning (e.g., turn scanning ON and OFF, pause the scanning, etc.) at the intentional gaps (332, 532). Alternatively, there may be a device (e.g., a computer with instructions) that interfaces the non-contact thermal detector (340, 540) and the printing head (320, 520) that excludes the thermal signal profile of the intentional gaps (332, 532) from the reprinting process.

As seen in FIG. 3B, the heating unit (350) may be disposed on a side of the substrate (310) that is along the print direction and may uniformly heat the conductive pattern (330) across the print direction.

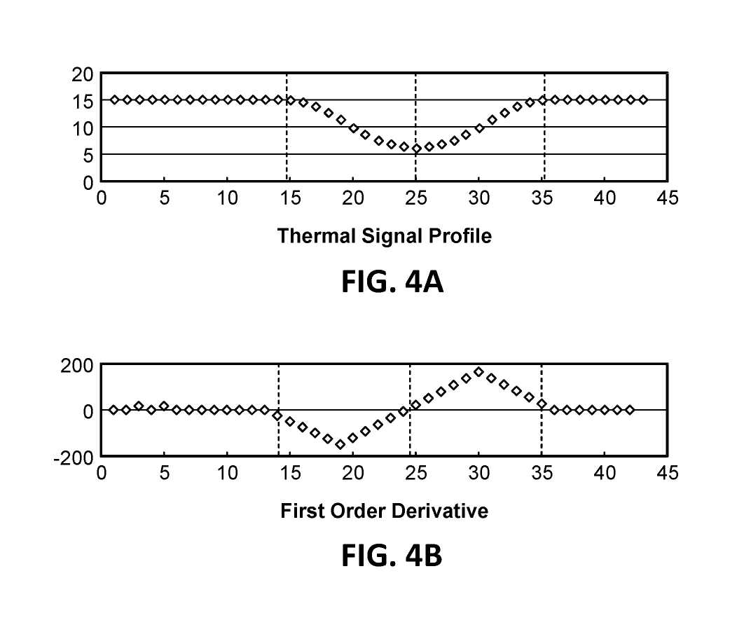

FIGS. 4A-4B show a thermal signal profile and a first order derivative, respectively, of the thermal signal profile around a fault (331) when the conductive pattern (330) is uniformly heated. As seen in FIG. 4A, the thermal signal profile of the fault (331) (i.e., between approximately 15 and 35 on the horizontal axis of FIG. 4A) has lower intensity than the thermal signal profile around the fault (331) (i.e., lower than approximately 15 or higher than approximately 35 on the horizontal axis of FIG. 4A). The difference between values of the thermal signal profile around the fault (331) and values of the thermal signal profile within the fault (331) may be used to detect the location of the fault (331) (i.e., between approximately 15 and 35 on the horizontal axis of FIG. 4A).

In one or more embodiments of the invention, mathematical calculations on the thermal signal profile such as first order derivative of the thermal signal profile may be used to locate the fault (331). Mathematical calculations may be used when a signal to noise ratio of the thermal signal profile is high. For example, FIG. 4B shows the first order derivative of the thermal signal profile of FIG. 4A. As seen in FIG. 4B, the first order derivative of the thermal signal profile of FIG. 4A at locations lower than approximately 15 or higher than approximately 35 on the horizontal axis is approximately zero. Alternatively, the first order derivative of the thermal signal profile of FIG. 4A at locations between approximately 15 and 35 on the horizontal axis changes between approximately −200 and 200. Therefore, the differences between the first order derivatives of the thermal signal profile may determine the location of the fault.

As seen in FIG. 5B, the heating unit (550A, 550B) may be disposed at an end of the substrate (510) and the heating unit (550A, 550B) may heat the conductive pattern (530) with a gradient along the print direction. For example, the temperature of a location of the conductive pattern (530) and the distance of the location from the heating unit (550A, 550B) may have a negative linear relationship (i.e., the temperature of the location decreases with a slope as the distance increases). In one or more embodiments of the invention, heating units (550A, 550B) may be disposed at each end of the substrate (510) in such a way that the direction of the temperature gradient may change (e.g., changing from decreasing to increasing along the print direction) by individually switching the heating units (550A, 550B) OFF or ON.

In one or more embodiments of the invention, the heating units (550A, 550B) at the ends of the substrate (510) may be designed in such a way that by switching both of the heating units (550A, 550B) to ON, the temperature gradient across the printing line may be modified (e.g., in to a uniform temperature along the print direction).

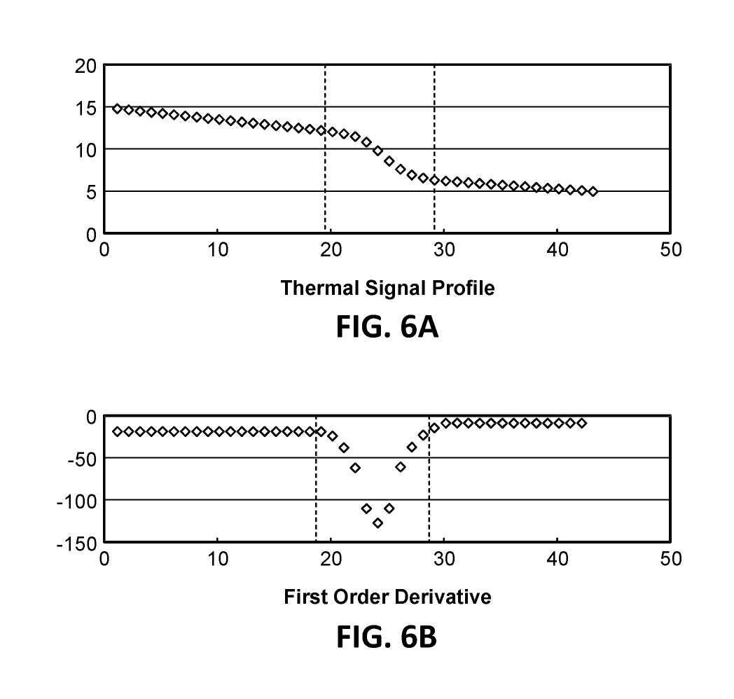

FIGS. 6A-4B show a thermal signal profile and a first order derivative, respectively, of the thermal signal profile around a fault (531) when the temperature of the conductive pattern (530) has a gradient across the print direction. As seen in FIG. 6A, the thermal signal profile of the fault (531) (i.e., between approximately 20 and 30 on the horizontal axis of FIG. 6A) has a different slope values than the slope values of the thermal signal profile around the fault (531) (i.e., lower than approximately 20 or higher than approximately 30 on the horizontal axis of FIG. 6A). The differences between the slope values of the thermal signal profile around the fault (531) and the slope values of the thermal signal profile within the fault (531) may be used to detect the location of the fault (531) (i.e., between approximately 20 and 30 on the horizontal axis of FIG. 6A).

FIG. 6B shows the first order derivative (i.e., the slope values) of the thermal signal profile of FIG. 6A. As seen in FIG. 6B, the absolute slope values of the first order derivative of the thermal signal profile of FIG. 6A at locations lower than approximately 20 or higher than approximately 30 on the horizontal axis is lower than approximately 25. Alternatively, the absolute slope values of the first order derivative of the thermal signal profile of FIG. 6A at locations between approximately 20 and 30 on the horizontal axis changes between approximately 25 and 125.

One of ordinary skill in the art will appreciate that other mathematical methods (e.g., higher order derivatives of the thermal signal profile) may be used to determine the locations of the faults.

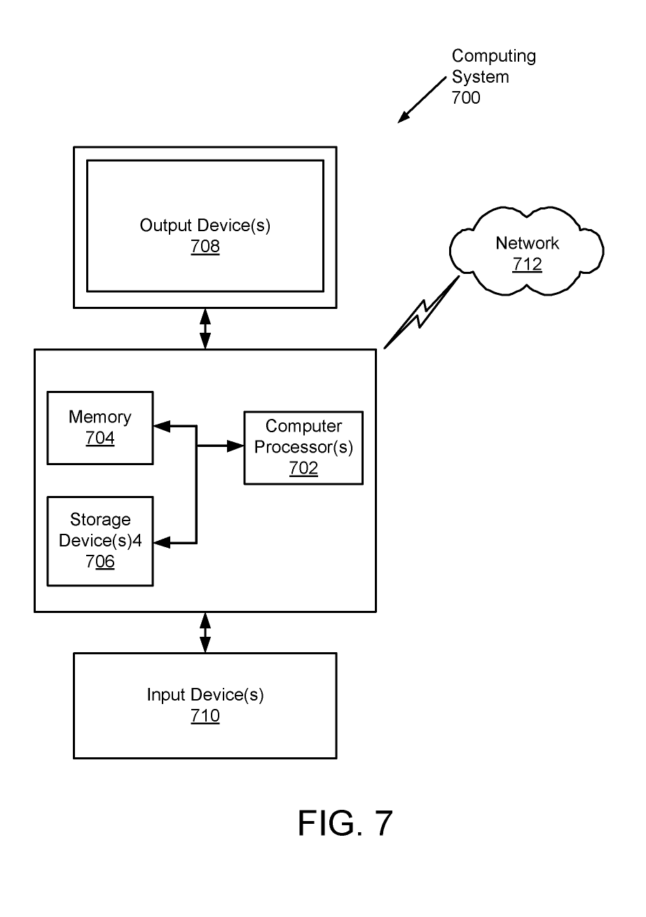

Embodiments of the invention may be implemented on virtually any type of computing system, regardless of the platform being used. For example, the computing system may be one or more mobile devices (e.g., laptop computer, smart phone, personal digital assistant, tablet computer, or other mobile device), desktop computers, servers, blades in a server chassis, or any other type of computing device or devices that includes at least the minimum processing power, memory, and input and output device(s) to perform one or more embodiments of the invention. For example, as shown in FIG. 7, the computing system (700) may include one or more computer processor(s) (702), associated memory (704) (e.g., random access memory (RAM), cache memory, flash memory, etc.), one or more storage device(s) (706) (e.g., a hard disk, an optical drive such as a compact disk (CD) drive or digital versatile disk (DVD) drive, a flash memory stick, etc.), and numerous other elements and functionalities. The computer processor(s) (702) may be an integrated circuit for processing instructions. For example, the computer processor(s) may be one or more cores, or micro-cores of a processor. The computing system (700) may also include one or more input device(s) (710), such as a touchscreen, keyboard, mouse, microphone, touchpad, electronic pen, or any other type of input device. Further, the computing system (700) may include one or more output device(s) (708), such as a screen (e.g., a liquid crystal display (LCD), a plasma display, touchscreen, cathode ray tube (CRT) monitor, projector, or other display device), a printer, external storage, or any other output device. One or more of the output device(s) may be the same or different from the input device(s). The computing system (700) may be connected to a network (712) (e.g., a local area network (LAN), a wide area network (WAN) such as the Internet, mobile network, or any other type of network) via a network interface connection (not shown). The input and output device(s) may be locally or remotely (e.g., via the network (712)) connected to the computer processor(s) (702), memory (704), and storage device(s) (706). Many different types of computing systems exist, and the aforementioned input and output device(s) may take other forms.

Software instructions in the form of computer readable program code to perform embodiments of the invention may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that when executed by a processor(s), is configured to perform embodiments of the invention.

Further, one or more elements of the aforementioned computing system (700) may be located at a remote location and be connected to the other elements over a network (712). Further, one or more embodiments of the invention may be implemented on a distributed system having a plurality of nodes, where each portion of the invention may be located on a different node within the distributed system. In one embodiment of the invention, the node corresponds to a distinct computing device. Alternatively, the node may correspond to a computer processor with associated physical memory. The node may alternatively correspond to a computer processor or micro-core of a computer processor with shared memory and/or resources.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method for detecting faults in a conductive circuitry, the method comprising:
printing the conductive circuitry on top of a substrate using a printing head;
heating the conductive circuitry with a heat source;
scanning the heated conductive circuitry with a non-contact thermal detector;
detecting, with the non-contact thermal detector and concurrently with the printing of the conductive circuitry, the faults where the printing head failed to print; and
reprinting the faults with the printing head.

2. The method of claim 1, wherein the non-contact thermal detector moves and scans across a length of the substrate in a synchronized manner with movements of the printing head across the length of the substrate.

3. The method of claim 1, wherein the non-contact thermal detector avoids scanning intentional gaps designed in the conductive circuitry.

4. The method of claim 1, wherein the conductive circuitry is heated without heating the substrate.

5. The method of claim 4, wherein the conductive circuitry is heated by one selected from a group consisting of: induction, microwave, and radio frequency waves.

6. The method of claim 5, wherein the conductive circuitry is heated evenly across a surface of the substrate.

7. The method of claim 5, wherein the conductive circuitry is heated from one end of the substrate.

8. The method of claim 1, wherein the non-contact thermal detector is a thermal sensor array.

9. The method of claim 8, wherein the thermal sensor array is one selected from a group consisting of: thermal IR, line-scanner, and fiber optic thermometer.

10. The method of claim 1, further comprising:
calculating a first derivative of an output of the non-contact thermal detector to locate the faults.

11. The method of claim 1, wherein the printed head is disposed on top of the substrate and the non-contact thermal detector is disposed under the substrate.

12. A non-transitory computer readable medium (CRM) storing instructions that causes a print server to perform an operation for detecting faults in a conductive circuitry embodied therein, the operation comprising:
printing the conductive circuitry on top of a substrate using a printing head;
heating the conductive circuitry with a heat source;
scanning the heated conductive circuitry with a non-contact thermal detector;
detecting, with the non-contact thermal detector and concurrently with the printing of the conductive circuitry, the faults where the printing head failed to print; and
reprinting the faults with the printing head.

13. The CRM according to claim 12, wherein the non-contact thermal detector moves and scans across a length of the substrate in a synchronized manner with movements of the printing head across the length of the substrate.

14. The CRM according to claim 12, wherein the non-contact thermal detector avoids scanning intentional gaps designed in the conductive circuitry.

15. The CRM according to claim 12, wherein the conductive circuitry is heated without heating the substrate.

16. The CRM according to claim 15, wherein the conductive circuitry is heated by one selected from a group consisting of: induction, microwave, and radio frequency waves.

17. The CRM according to claim 16, wherein the conductive circuitry is heated evenly across a surface of the substrate.

18. The CRM according to claim 16, wherein the conductive circuitry is heated from one end of the substrate.

19. A system for detecting faults in a conductive circuitry, the system comprising:
a memory; and
a computer processor connected to the memory, wherein the computer processor causes a print unit coupled to the system to:
print the conductive circuitry on top of a substrate using a printing head;
heat the conductive circuitry with a heat source;
scan the heated conductive circuitry with a non-contact thermal detector;
detect, with the non-contact thermal detector and concurrently with the print of the conductive circuitry, the faults where the printing head failed to print; and
reprint the faults with the printing head.

20. The system according to claim 19, wherein the printed head is disposed on top of the substrate and the non-contact thermal detector is disposed under the substrate.
